(19) United States
(12) Patent Application Publication
(10) Pub. No.: US 2012/0222615 A1
(43) Pub. Date: Sep. 6, 2012

(54) FILM DEPOSITION APPARATUS

(75) Inventors: Hitoshi KATO, Iwate (JP); Tsuneyuki Okabe, Iwate (JP); Manabu Honma, Iwate (JP); Takeshi Kumagai, Iwate (JP); Yasushi Takeuchi, Iwate (JP)

(73) Assignee: Tokyo Electron Limited, Tokyo (JP)

(21) Appl. No.: 13/221,188

(22) Filed: Aug. 30, 2011

(30) Foreign Application Priority Data
Sep. 3, 2010 (JP) 2010-197953

(51) Int. Cl. C23C 16/455

(52) U.S. Cl. 118/719

(57) ABSTRACT

A film deposition apparatus includes a first turntable including at least ten substrate receiving areas that receive corresponding 300 mm substrates; a first reaction gas supplying portion arranged in a first area inside the chamber to supply a first reaction gas; a second reaction gas supplying portion arranged in a second area away from the first reaction gas supplying portion along the rotation direction of the first turntable to supply a second reaction gas; and a separation area arranged between the first and the second areas. The separation area includes a separation gas supplying portion that supplies a separation gas that separates the first reaction and the second reaction gases, and a ceiling surface having a height so that a pressure in a space between the ceiling surface and the first turntable is higher with the separation gas than pressures in the first and the second areas.

### CROSS-REFERENCE TO RELATED APPLICATION

This application claims the benefit of priority of Japanese Patent Application No. 2010-197953, filed on Sep. 3, 2010 with the Japanese Patent Office, the entire contents of which are hereby incorporated by reference.

### BACKGROUND OF THE INVENTION

1. Field of the Invention

The present invention relates to a film deposition apparatus for depositing a film on a substrate by carrying out a cycle of alternately supplying at least two kinds of reaction gases that react with each other to the substrate to produce a layer of a reaction product in a chamber.

2. Description of the Related Art

As one of fabrication processes of semiconductor integrated circuits (ICs), there is a film deposition method called Atomic Layer Deposition (ALD) or Molecular Layer Deposition. This film deposition method may be carried out in a turntable type ALD apparatus. An example of such an ALD apparatus has been proposed by the applicant of this patent application (See Patent Document 1 below).

The ALD apparatus of Patent Document 1 is provided with a turntable that is arranged in a vacuum chamber and on which, for example, five substrates are placed, a first reaction gas supplying part that supplies a first reaction gas toward the substrates on the turntable, a second reaction gas supplying part that supplies a second reaction gas toward the substrates on the turntable and is arranged away from the first reaction gas supplying part in the vacuum chamber. In addition, the vacuum chamber includes a separation area that separates a first process area in which the first reaction gas is supplied from the first reaction gas supplying part and a second process area in which the second reaction gas is supplied from the second reaction gas supplying part. The separation area includes a separation gas supplying part that supplies a separation gas and a ceiling surface that creates a thin space with respect to the turntable thereby to maintain the separation area at a higher pressure than those in the first and the second process areas with the separation gas from the separation gas supplying part.

With such a configuration, because the first and the second process areas are kept at a sufficiently higher pressure, the first reaction gas and the second reaction gas can be impeded from being intermixed in the vacuum chamber, even when the turntable is rotated at higher rotational speed, thereby improving production throughput.

Patent Document 1: Japanese Patent Application Laid-Open Publication No. 2010-56470.

### SUMMARY OF THE INVENTION

However, further improvement of the production throughput is increasingly demanded. In order to meet the demand, a large-scale ALD apparatus has been investigated by integrating plural vacuum chambers in the ALD apparatus. In addition, use of large substrates has been attempted in order to further improve and to reduce production costs of the ICs.

However, the large-scale ALD apparatus tends to require additional ancillary facilities that, for example, supply the reaction gases and evacuate the vacuum chambers, thereby leading to an increased production cost and increased footprint of the ALD apparatus.

The present invention provides a film deposition apparatus that makes it possible to improve production throughputs while avoiding an excessive increase of ancillary facilities and/or footprint thereof.

According to an aspect of the present invention, there is provided a film deposition apparatus for depositing a film on a substrate by carrying out a cycle of alternately supplying at least two kinds of reaction gases that react with each other to the substrate to produce a layer of a reaction product in a chamber. The film deposition apparatus includes a first turntable rotatably provided in the chamber, wherein the first turntable includes at least ten substrate receiving areas in each of which a substrate having a diameter of 300 mm is placed; a first reaction gas supplying portion that is arranged in a first area inside the chamber, extends in a direction transverse to a rotation direction of the first turntable, and supplies a first reaction gas toward the first turntable; a second reaction gas supplying portion that is arranged in a second area that is away from the first reaction gas supplying portion along the rotation direction of the first turntable, extends in a direction transverse to the rotation direction of the first turntable, and supplies a second reaction gas toward the first turntable; a first evacuation port provided for the first area; a second evacuation port provided for the second area; and a separation area arranged between the first area and the second area. The separation area includes a separation gas supplying portion that supplies a separation gas that separates the first reaction gas and the second reaction gas in the chamber, and a ceiling surface having a height from the first turntable so that a pressure in a space created between the ceiling surface and the first turntable is higher with the separation gas supplied from the separation gas supplying portion than pressures in the first area and the second area.

### BRIEF DESCRIPTION OF THE DRAWINGS

FIG. 1 is a plan view of a film deposition apparatus according to a first embodiment of the present invention;

FIG. 2 is a cross-sectional view of the film deposition apparatus of FIG. 1;

FIG. 3 is an explanatory view for explaining a turntable and a core portion in the film deposition apparatus of FIG. 1;

FIG. 4 is a partial cross-sectional view of a vacuum chamber of the film deposition apparatus, taken along an auxiliary line S in FIG. 1

FIG. 5 is an explanatory view for explaining a wafer receiving area in the turntable of the film deposition apparatus of FIG. 1;

FIG. 6A is an explanatory view for explaining advantages of the film deposition apparatus of FIG. 1;

FIG. 6B is another explanatory view for explaining advantages of the film deposition apparatus of FIG. 1;

FIG. 7 is a schematic view illustrating an altered example of the turntable of the film deposition apparatus of FIG. 1;

FIG. 8 is a plan view schematically illustrating a film deposition apparatus according to a second embodiment of the present invention;

FIG. 9 is a perspective view illustrating a gas injector provided in the film deposition apparatus of FIG. 8;

FIG. 10 is a cross-sectional view illustrating the gas injector of FIG. 9;

FIG. 11 is a partially enlarged perspective view of the gas injector of FIG. 9;

FIG. 12 is a plan view schematically illustrating a film deposition apparatus according to a third embodiment; and

FIG. 13 is a graph for explaining advantages of the film deposition apparatus according to the third embodiment.

### DETAILED DESCRIPTION OF THE PREFERRED EMBODIMENT

According to an embodiment of the present invention, a film deposition apparatus that makes it possible to improve production throughputs while avoiding an excessive increase of ancillary facilities and/or footprint thereof is provided.

Non-limiting, exemplary embodiments of the present invention will now be described with reference to the accompanying drawings. In the drawings, the same or corresponding reference marks are given to the same or corresponding members or components. It is noted that the drawings are illustrative of the invention, and there is no intention to indicate scale or relative proportions among the members or components. Therefore, the specific size should be determined by a person having ordinary skill in the art in view of the following non-limiting embodiments.

### A First Embodiment

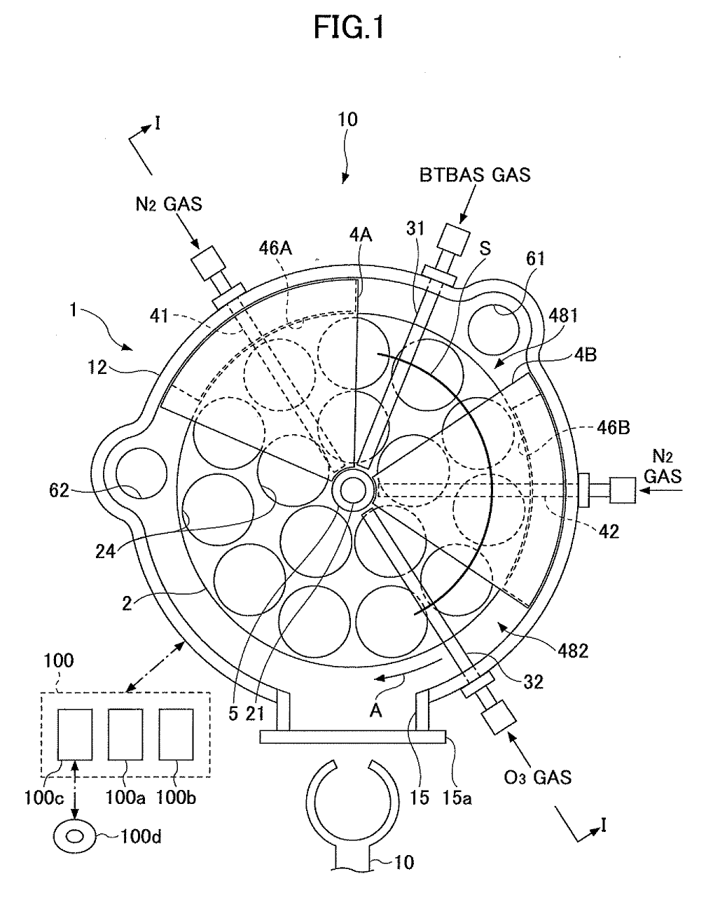

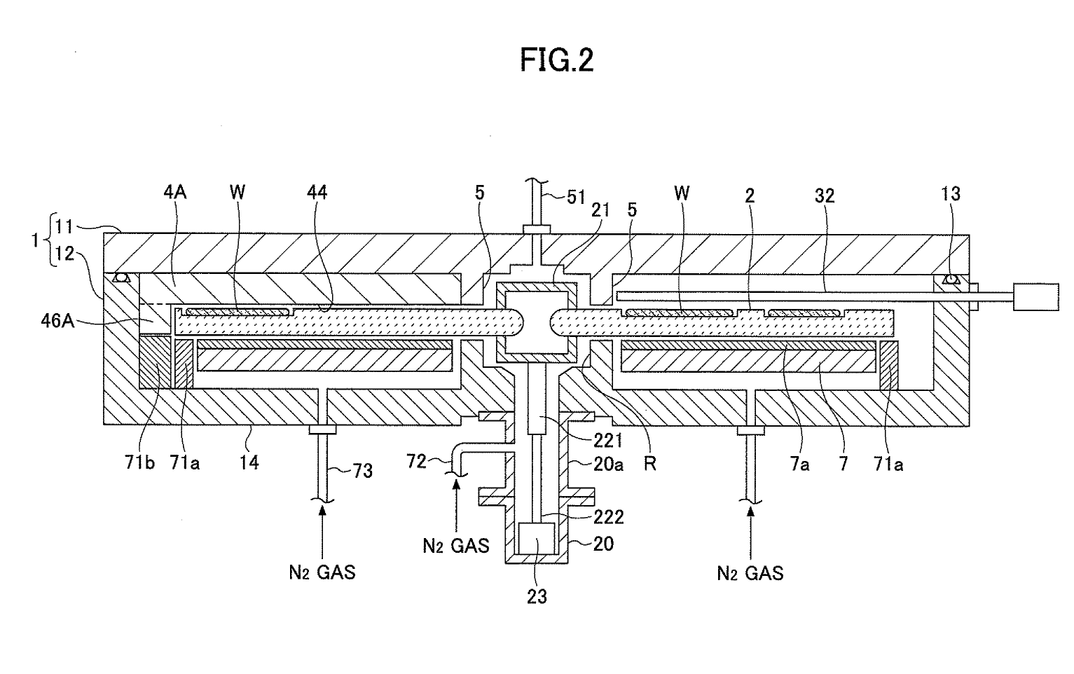

Referring to FIGS. 1 through 6B, a film deposition apparatus according to a first embodiment of the present invention is explained. As shown in FIGS. 1 and 2, a film deposition apparatus 10 according to this embodiment is provided with a vacuum chamber 1 having a flattened cylinder shape, and a turntable 2 that is located inside the vacuum chamber 1 and has a rotation center at a center of the vacuum chamber 1.

As shown in FIG. 2, which is a cross-sectional view taken along an I-I line of FIG. 1, the vacuum chamber 1 includes a chamber body 12 having a shape of a flattened cylinder with a bottom, and a ceiling plate 11 that is placed on the chamber body 12 via a ceiling member such as an O ring 13 in an airtight manner. The ceiling plate 11 and the chamber body 12 are made of metal such as aluminum (Al).

Referring to FIG. 1, plural circular substrate receiving areas 24, each of which receives a wafer W, are formed in an upper surface of the turntable 2. Specifically, eleven substrate receiving areas 24 are provided in an outer area along the circumference of the turntable 2 and five substrate receiving areas 24 are provided inside of the eleven substrate receiving areas 24, in this embodiment. Each of the substrate receiving areas 24 is configured as a concave portion having a diameter slightly larger, for example, by 4 mm than the diameter of the wafer W and a depth equal to a thickness of the wafer W. With this, when the wafer W is placed in the wafer receiving area 24, a surface of the wafer W is at the same elevation of a surface of an area of the turntable 2, the area excluding the substrate receiving areas 24. Because there is substantially no step between the upper surface of the wafer W and the upper surface of the turntable 2, gas flow turbulence which may affect thickness uniformity across the wafer W is not caused. In addition, because the wafer W is accommodated within the wafer receiving area 24, the wafer W is not thrown out even when the turntable 2 is rotated. Incidentally, a wafer guide ring described later can be used in order to keep the wafer W in the wafer receiving area 24.

Incidentally, the wafer having a diameter of 300 mm (or a 300 mm wafer) means a wafer commercially available as a 300 mm wafer or a 12 inch wafer, but does not mean a diameter of the wafer is exactly 300 mm. The same is true for a wafer having a diameter of 450 mm (or 450 mm wafer), which is described later.

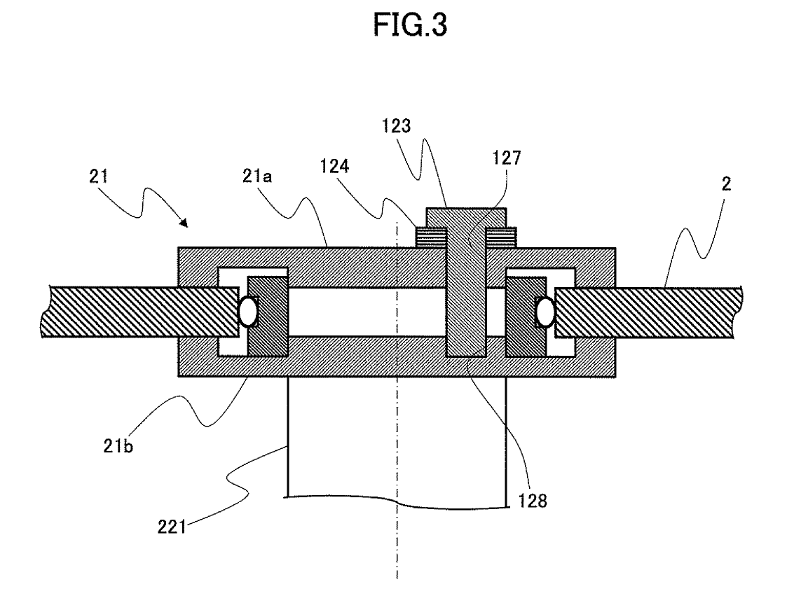

In addition, as shown in FIG. 2, the turntable 2 has an opening at the center thereof, and is supported from above and below at and around the opening by a cylindrically shaped core portion 21. The core portion 21 is composed of an upper hub 21a and a lower hub 21b, as shown in FIG. 3. The upper hub 21a has a through-hole 127 at an off-centered position, and the lower hub 21b has a screw hole 128 at a position corresponding to the through-hole 127 of the upper hub 21a. A bolt 123 is inserted into the through-hole 127 of the upper hub 21a, together with a washer 124, and threaded into the screw hole 128 of the lower hub 21b, so that the upper hub 21a and the lower hub 21b are pushed onto the turntable 2 from the above and the below, respectively, so that the turntable 2 is firmly fixed. With this, the turntable 2 can be replaced by removing and then attaching the bolt 123. Incidentally, although only one bolt 123 is illustrated in FIG. 3, plural of the through holes 127 and corresponding plural of the screw holes 128 may be provided in the core portion 21, so that the core portion 21 is more firmly fixed by corresponding plural of the bolts 123.

The lower hub 21b is fixed on a top end of a rotational shaft 221. As shown in FIG. 2, the rotational shaft 221 extends in a vertical direction to go through a bottom portion 14 of the chamber body 12 and is fixed at the lower end to a driving mechanism 23 via a rotational shaft 222. The core portion 21, the rotational shaft 221, and the rotational shaft 222 share a rotational axis, and are rotated by the driving mechanism 23, which in turn rotates the turntable 2.

The rotational shaft 221 and the driving mechanism 23 are housed in a case body 20 having a shape of a cylinder with an open top and a closed bottom. The case body 20 is fixed to a bottom surface of the bottom portion 14 via a flanged pipe portion 20a in an airtight manner, so that an inner environment of the case body 20 is isolated from an outer environment.

Referring again to FIG. 1, the vacuum chamber 1 is provided with two convex portions 4A, 4B that are arranged above the turntable 2 and away from each other along a circumferential direction of the vacuum chamber 1. As shown, the convex portions 4A, 4B have a top view shape of a truncated sector. Each of the convex portions 4A, 4B is located so that an inner arc thereof comes close to a protrusion portion 5 attached on the lower surface of the ceiling plate 11 in order to surround the core portion 21, and an outer arc thereof extends along an inner circumferential surface of the chamber body 12. The convex portions 4A, 4B are attached on the lower surface of the ceiling plate 11 (see FIG. 2 for the convex portion 4A) although the ceiling plate 11 is omitted in FIG. 1 for the convenience of the explanation.

Although not illustrated, the convex portion 4B is arranged in the same manner as the convex portion 4A. Because the convex portion 4B has substantially the same configuration and function as the convex portion 4A, the following explanation is made referring mainly to the convex portion 4B. Incidentally, the convex portions 4A, 4B may be made of, for example, metal such as aluminum.

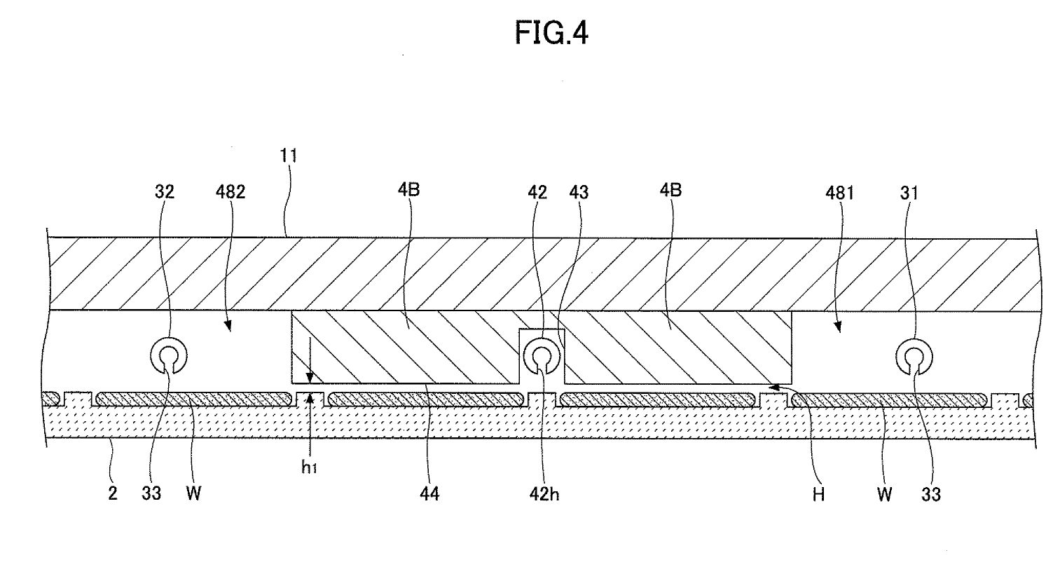

Referring to FIG. 4, the convex portion 4B has a groove portion 43 that extends in the radial direction so that the groove portion 43 substantially bisects the convex portion 4B. A separation gas nozzle 42 is located in the groove portion 43. The separation gas nozzle 42 is introduced into the vacuum chamber 11 from a circumferential portion of the chamber body 12 and extends in the radial direction of the vacuum chamber 1. Specifically, a base end portion of the separation gas nozzle 42 is attached in the circumferential portion of the chamber body 12, so that the separation gas nozzle 42 is supported parallel with the upper surface of the turntable 2. Incidentally, a separation gas nozzle 41 is arranged in the groove portion 43 of the convex portion 4A in the same manner.

The separation gas nozzle 42 is connected to a gas supplying source (not shown) of a separation gas, which may be an inert gas including nitrogen (N₂) gas. Alternatively, the separation gas is not limited to the inert gas, but may be any gas as long as the separation gas does not affect the film deposition. In this embodiment, the N₂ gas is used as the separation gas. In addition, the separation gas nozzle 42 has plural ejection holes 42h (FIG. 4) through which the N₂ gas is ejected toward the turntable 2. The ejection holes 42h have a diameter of about 0.5 mm and are arranged at intervals of about 10 mm along the longitudinal direction of the separation gas nozzle 42. Moreover, a distance between the separation gas nozzle 42 and the upper surface of the turntable 2 may be in a range from about 0.5 mm through 4 mm.

As shown in FIG. 4, which is a cross-sectional view taken along an auxiliary line S in FIG. 1), a separation space H is formed by the turntable 2 and the convex portion 4B. A height h1 of the separation space H (or a height from the upper surface of the upper surface to a ceiling surface 44 (or a lower surface of the convex portion 4B)) is preferably in a range from about 0.5 mm through about 10 mm. The height may be about 3.5 mm through about 6.5 mm in order to prevent the turntable 2 from hitting the ceiling surface 44, although the height h1 is preferably smaller. On respective sides of the convex portion 4B, there are formed a first area 481 and a second area 482, which are defined by the upper surface of the turntable 2 and a lower surface of the ceiling plate 11. Heights of the first area 481 and the second area 482 (or heights of the lower surface of the ceiling plate 11 from the upper surface of the turntable 2) may be in a range from about 15 mm through about 150 mm. A reaction gas nozzle 31 is provided in the first area 481, and a reaction gas nozzle 32 is provided in the second area 482. The reaction gas nozzles 31, 32 are introduced into the vacuum chamber 1 through a circumferential wall of the chamber body 12, and extend in radius directions, as shown in FIG. 1. Each of the reaction gas nozzles 31, 32 has plural ejection holes 33 that are open downward and arranged at about 10 mm intervals along the longitudinal directions of the reaction gas nozzles 31, (or 32), as shown in FIG. 4. Each of the plural ejection holes 33 has a diameter of about 0.5 mm. A first reaction gas is supplied from the reaction gas nozzle 31, and a second reaction gas is supplied from the reaction gas nozzle 32. In this embodiment, the reaction gas nozzle 31 is connected to a gas source of a bis (tertiary-butylamino) silane (BTBAS) gas as silicon source gas, and the reaction gas nozzle 32 is connected to a gas source of ozone gas as an oxidizing gas that oxidizes the BTBAS into silicon oxide.

When the N₂ gas is supplied from the separation gas nozzle 41, the N₂ gas flows to the first area 481 and the second area 482 from the separation space H. Because the height h1 of the separation space H is smaller than the heights of the first area 481 and the second area 482, as explained above, a pressure of the separation space H can be easily greater than pressures of the first area 481 and the second area 482. In other words, the height and width of the convex portion 4B and a flow rate of the N₂ gas from the separation gas nozzle 41 is preferably determined so that the pressure of the separation space H can be easily greater than the pressures of the first area 481 and the second area 482. When determining flow rates of the first reaction gas and the second reaction gas, the rotational speed of the turntable 2 and the like are preferably taken into consideration. In such a manner, the separation space H can provide a pressure wall against the first area 481 and the second area 482, thereby certainly separating the first area 481 and the second area 482.

Specifically, when the first reaction gas (e.g., BTBAS gas) is supplied from the reaction gas nozzle 31 to the first area 481, even if the first reaction gas flows toward the convex portion 4B due to the rotation of the turntable 2, the first reaction gas cannot flow through the separation space H into the second area 482 because of the pressure wall created in the separation space H, as shown in FIG. 4. In a similar way, when the second reaction gas (e.g., ozone gas) is supplied from the reaction gas nozzle 32 to the second area 482, even if the second reaction gas flows toward the convex portion 4A (FIG. 1) due to the rotation of the turntable 2, the second reaction gas cannot flow through the separation space H into the first area 481 because of the pressure wall created in the separation space H. Therefore, the first reaction gas and the second reaction gas are effectively impeded from being intermixed through the separation space H.

With such a configuration, the BTBAS gas and the ozone gas are certainly separated even when the turntable 2 is rotated at a rotational speed of about 240 revolutions per minute, according to the inventors' investigations.

Referring again to FIG. 2, the protrusion portion 5, which is attached on the lower surface of the ceiling plate 11 in order to surround the core portion 21 that firmly fixes the turntable 2, comes close to the upper surface of the turntable 2. In the illustrated sample, a lower surface of the protrusion portion 5 is substantially at the same elevation as the ceiling surface 44 (or the lower surface of the convex portion 4B (or 4A)). In other words, a height of the lower surface of the protrusion portion 5 from the upper surface of the turntable 2 is the same as the height h1 of the ceiling surface 44. In addition, a distance between the lower surface of the protrusion portion 5 and the ceiling plate 11 and a distance between an inner circumferential surface of the protrusion portion 5 and an outer circumferential surface of the core portion 21 are substantially the same as the height h1 of the ceiling surface 44, in this embodiment. A separation gas supplying pipe 51 is connected to an upper center portion of the ceiling plate 11, and supplies N₂ gas. With this N₂ gas supplied from the gas supplying pipe 51, spaces between the core portion 21 and the ceiling plate 11, between the inner circumferential surface of protrusion portion 5, and between the protrusion portion 5 and the turntable 2 can have higher pressure than the pressures of the first area 481 and the second area 482. Incidentally, the spaces may be referred to as a center space hereinafter, for the sake of explanation. Therefore, the center space can provide a pressure wall against the first area 481 and the second area 482, thereby certainly separating the first area 481 and the second area 482. Namely, the first reaction gas (e.g., BTBAS gas) and the second reaction gas (e.g., ozone gas) are effectively impeded from being intermixed through the center space.

As shown in FIG. 2, a ring-shaped heater unit 7 as a heating portion is provided in a space between the bottom portion 14 of the chamber body 12 and the turntable 2, so that the wafers W placed on the turntable 2 are heated through the turntable 2 at a predetermined temperature. In addition, a block member 71a is provided beneath the turntable 2 and near the outer circumference of the turntable 2 in order to surround the heater unit 7, so that the space where the heater unit 7 is housed is partitioned from the outside area of the block member 71a. Plural purge gas supplying pipes 73 are connected at predetermined angular intervals to the space where the heater unit 7 is housed in order to purge this space. Incidentally, a protection plate 7a that protects the heater unit 7 is supported above the heater unit 7 by the block member 71a and a raised portion R (described later). With the protection plate 7a, the heater unit 7 can be protected even when the BTBAS gas and/or the O₃ gas flow below the turntable 2. The protection plate 7a is preferably made of, for example, quartz.

Incidentally, the heater unit 7 may be configured of plural lamp heaters that are placed concentrically. With this, each of the plural lamp heaters can be separately controlled, thereby uniformly heating the turntable 2.

Referring again to FIG. 2, the bottom portion 14 has a raised portion R in an inside area of the ring-shaped heater unit 7. The top surface of the raised portion R comes close to the back surface of the turntable 2 and the core portion 21, leaving slight gaps between the raised portion R and the turntable 2 and between the raised portion R and the core portion 21. In addition, the bottom portion 14 has a center hole through which the rotational shaft 221 passes. The inner diameter of the center hole is slightly larger than the diameter of the rotational shaft 221, leaving a gap that allows pressure communication with the case body 20 through the flanged pipe portion 20a. A purge gas supplying pipe 72 is connected to an upper portion of the flanged pipe portion 20a.

With such a configuration, N₂ gas flows from the purge gas supplying pipe 72 into the space where the heater unit 7 is housed through the gap between the center hole of the bottom portion 14 of the chamber body 12 and the rotational shaft 22, and between the raised portion R and the lower surface of the turntable 2. The N₂ gas flows through a gap between the block member 71a and the lower surface of the turntable 2, together with the N₂ gas from the purge gas supplying pipes 73, into an evacuation port 61. The N₂ gases flowing in such a manner can serve as separation gases that impede the BTBAS (or O₃ gas) from being intermixed with the O₃ gas (or BTBAS gas) by way of the space below the turntable 2.

Referring again to FIG. 1, the convex portion 4B has a bent portion 46B that bends in an L-shape from an outer circumferential portion of the convex portion 4B, and extends between the outer circumference of the turntable 2 and the inner circumferential surface of the chamber body 12. In addition, the convex portion 4A has a bent portion 46A that bends in an L-shape from an outer circumferential portion of the convex portion 4A, and extends between the outer circumference of the turntable 2 and the inner circumferential surface of the chamber body 12. Because the bent portions 46A, 46B have the same structure, the bent portion 46A is explained referring to FIG. 2 in the following for the sake of convenience. As shown, the bent portion 46A is integrally formed with the convex portion 4A in this embodiment. The bent portion 46A substantially fills the gap between the space between the turntable 2 and the chamber body 12, thereby impeding the first reaction gas (e.g., BTBAS gas) from being intermixed with the second reaction gas (e.g., O₃ gas) by way of this space. Gaps between the chamber body 12 and the bent portion 46A, and between the bent portion 46A and the turntable 2 may be the same as the height h1 of the ceiling surface 44 from the upper surface of the turntable 2. Because of the bent portion 46A, the separation gas from the separation gas nozzle (FIG. 1) is less likely to flow outward into the space between the turntable 2 and the chamber body 12. Therefore, the bent portion 46A contributes to maintaining the higher pressure of the separation space H (the space between the turntable 2 and the convex portion 4A). Incidentally, because a block member 71b is provided below the bent portion 46A (or 468) in this embodiment, the higher pressure of the separation space H can be more effectively maintained.

Incidentally, the gaps between the bent portions 46A, 46B and the turntable 2 are preferably determined by taking into consideration thermal expansion of the turntable 2 so that the gaps become the same as, for example, the height h1 when the turntable 2 is heated by the heater unit 7.

As shown in FIG. 1, a part of the inner circumferential surface of the chamber body 12 is indented outward in the first area 481, and the evacuation port 61 is formed below the indented portion. In addition, another part of the inner circumferential surface of the chamber body 12 is indented outward in the second area 482, and an evacuation port 62 is formed below the indented portion. The evacuation ports 61, 62 are connected together or separately to an evacuation system including a pressure controller and a turbo molecular pump (not shown), so that an inner pressure of the vacuum chamber 1 is controlled. Because the evacuation port 61 is formed corresponding to the first area 481, and the evacuation port 62 is formed corresponding to the second area 482, the first area 481 is evacuated substantially exclusively through the evacuation port 61 and the second area 482 is evacuated substantially exclusively through the evacuation port 62. Therefore, the pressures of the first area 481 and the second area 482 tend to be lower than the pressure of the separation space H. In addition, the evacuation port 61 is positioned between the reaction gas nozzle 31 and the convex portion 4B located downstream relative to the reaction gas nozzle 31 along the rotation direction of the turntable 2. Additionally, the port 62 is positioned between the reaction gas nozzle 32 and the convex portion 4A located downstream relative to the reaction gas nozzle 32 along the rotation direction of the turntable 2. Specifically, the evacuation port 62 comes closer to the convex portion 4A. With these configurations, the first reaction gas (e.g., BTBAS gas) is substantially exclusively evacuated through the evacuation port 61, and the reaction gas (e.g., O₃ gas) is substantially exclusively evacuated through the evacuation port 62. Namely, such arrangements of the evacuation ports 61, 62 contribute to separating the first reaction gas and the second reaction gas.

Referring to FIG. 1, a transfer opening 15 is formed in the circumferential wall of the chamber body 12. The wafer W is transferred into or out from the vacuum chamber 1 through the transfer opening 15. The transfer opening 15 is provided with a gate valve 15a that opens or closes the transfer opening 15.

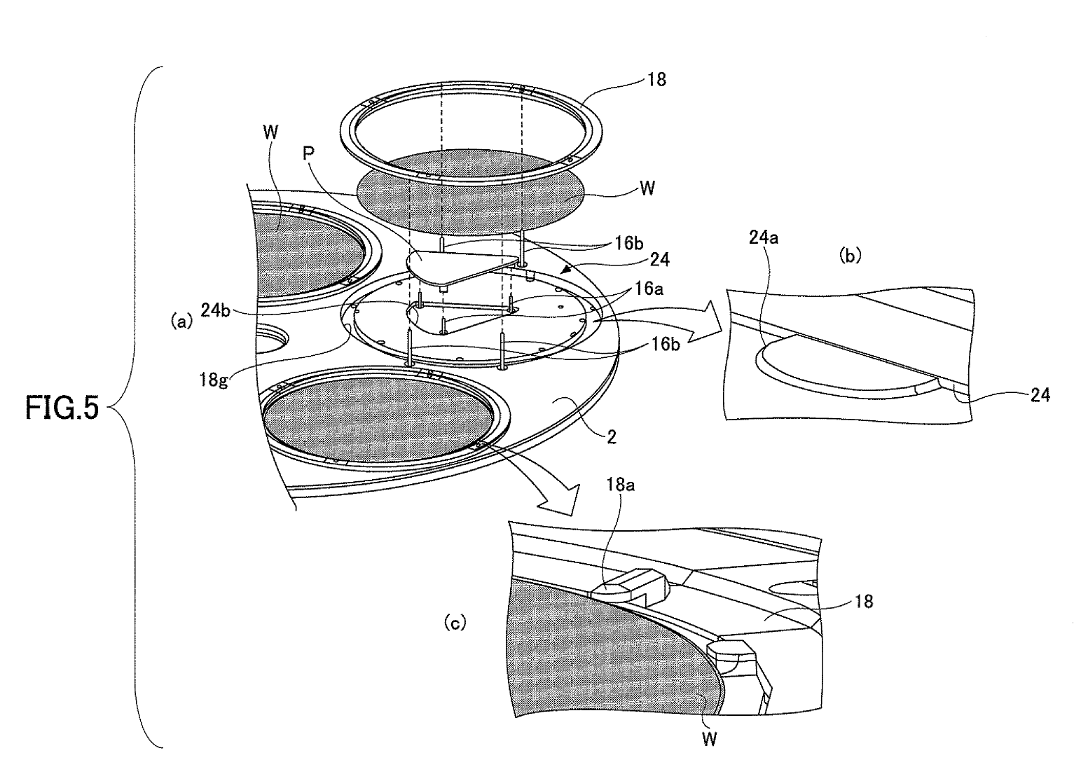

Next, a wafer guide ring and lift pins that place the wafer W onto the turntable 2 or bring the wafer W out from the turntable in cooperation with a transfer arm 10 are explained with reference to FIG. 5. Part (a) of FIG. 5 is a perspective view of a part of the turntable 2. As shown, three through-holes are formed in the wafer receiving area 24 of the turntable 2, and three lift pins 16a can move upward or downward through the corresponding through holes. The three lift pins 16a support a pusher P and move the pusher P upward or downward. In addition, the wafer receiving area 24 has an indent 24b that has a shape corresponding to the pusher P. When the lift pins 16a are brought down to allow the pusher P to be accommodated in the indent 24b, an upper surface of the pusher P is located at the same elevation as that of the bottom of the wafer receiving area 24. In addition, wafer supporting portions 24a are formed along the outer circumference of the wafer receiving area 24, as shown in part (b) of FIG. 5. Although not shown in the drawing, plural (e.g., eight) wafer supporting portions 24a are formed along the outer circumference of the wafer receiving area 24. When the wafer W is placed in the wafer receiving area 24, the wafer W is supported by the wafer supporting portions 24a. With this, a constant gap is maintained between the wafer W and the bottom surface of the wafer receiving area 24, and thus the lower surface of the wafer W does not contact the bottom surface of the wafer receiving area 24. Therefore, because the wafer W is heated via the gap by the turntable 2, the wafer W is uniformly heated.

Referring again to part (a) of FIG. 5, a guide groove 18g is formed around the wafer receiving area 24, so that a wafer guide ring 18 is fitted into the guide groove 18g. Part (c) of FIG. 5 illustrates the wafer guide ring 18 fitted in the guide groove 18g. As shown, the wafer guide ring 18 has an inner diameter that is greater than the diameter of the wafer W, and thus the wafer W is arranged within the wafer guide ring 18 when the wafer guide ring 18 is fitted into the guide groove 18g. In addition, claws 18a are formed on the upper surface of the wafer guide ring 18. The claws 18a extend toward the center of the wafer guide ring 18 so that they go beyond and are positioned above the edge of the wafer W that has been placed in the wafer receiving area 24. While the claws 18a do not touch the upper surface of the wafer W in normal conditions, they can keep the wafer W in the wafer receiving area 24, even if the wafer W may be brought upward by sudden changes in the inner pressure of the vacuum chamber 1 for some reasons.

In addition, four lift pins 16b that bring the wafer guide ring 18 upward or downward are formed outside of the guide groove 18g. While the wafer guide ring 18 is brought up by the lift pins 16b, the wafer W is transferred between the wafer guide ring 18 and the turntable 2 by the transfer arm (FIG. 1). After the pusher P is brought up by the lift pins 16a thereby to receive the wafer W from the transfer arm 10, the transfer arm 10 is withdrawn from the vacuum chamber 1 and the lift pins 16a are brought downward and the pusher P is accommodated in the indent 24b. With this, the wafer W is received by the wafer supporting portions 24a in the wafer receiving area 24. Next, the lift pins 16b are brought downward thereby to allow the wafer guide ring 18 to be accommodated in the guide groove 18g. With this, the wafer W is accommodated assuredly by the wafer guide ring 18.

In addition, the film deposition apparatus according to this embodiment is provided with a control portion 100 that controls total operations of the deposition apparatus, as shown in FIG. 1. The control portion 100 includes a process controller 100a formed of, for example, a computer, a user interface portion 100b, and a memory device 100c. The user interface portion 100b has a display that shows operations of the film deposition apparatus, and a key board and a touch panel (not shown) that allow an operator of the film deposition apparatus 10 to select a process recipe and an administrator of the film deposition apparatus to change parameters in the process recipe.

The memory device 100c stores a control program and a process recipe that cause the controlling portion 100 to carry out various operations of the deposition apparatus, and various parameters in the process recipe. These programs have groups of steps for carrying out a film deposition process described later, for example. These programs and process recipes are installed into and run by the process controller 100a by instructions from the user interface portion 100b. In addition, the programs are stored in a computer readable storage medium 100d and installed into the memory device 100c from the storage medium 100d through an interface (I/O) device corresponding to the computer readable storage medium 100d. The computer readable storage medium 100d may be a hard disk, a compact disc, a magneto optical disk, a memory card, a flexible disk, or the like. Moreover, the programs may be downloaded to the memory device 100c through a communications network.

Next, operations of the film deposition apparatus 100 (a film deposition method) are explained with reference to the drawings that have been referred to. First, the turntable 2 is rotated so that one of the five inner wafer receiving areas 24 is in alignment with the transfer opening 15, and then the gate valve 15a is opened. When the wafer guide ring 18 is brought up by the lift pins 16b, the wafer W is transferred into the vacuum chamber 1 by the transfer arm 10, and held between the turntable 2 and the wafer guide ring 18. After the pusher P is brought up by the lift pins 16a thereby to receive the wafer W, the transfer arm 10 is withdrawn from the vacuum chamber 1, and then the pusher P holding the wafer W is brought down by the lift pins 16a. With these procedures, the wafer W is placed in the wafer receiving area 24. Next, the wafer guide ring 18 is brought down by the lift pins 16b and fitted into the guide groove 18g. The above series of the procedures is repeated five times, so that the five wafers W are set in the corresponding inner wafer receiving areas 24. Subsequently, the same series of the procedures is repeated eleven times so that the eleven wafers W are set in the corresponding eleven outer wafer receiving areas 24. With this, the wafer transfer-in process is completed.

Next, the vacuum chamber 1 is evacuated by the evacuation mechanism (not shown), while the N₂ gas is supplied from the separation gas nozzles 41, 42, the separation gas supplying pipe 51, and the purge gas supplying pipes 72, 73, so that the vacuum chamber 1 is maintained at a predetermined pressure by the pressure controller (not shown). Then, the turntable 2 starts rotating in a clockwise direction when seen from above. The turntable 2 is heated at a predetermined temperature (e.g., about 300° C.) in advance by the heater unit 7, and thus the wafers W on the turntable 2 are heated at substantially the same temperature. After the wafers W are maintained at the temperature, the BTBAS gas is supplied to the first area 481 from the reaction gas nozzle 31, and the O₃ gas is supplied to the second area 482 from the reaction gas nozzle 32.

When the wafers W pass through below the reaction gas nozzle 31, the BTBAS gas is adsorbed on the upper surfaces of the wafers W, and the adsorbed BTBAS gas is oxidized by the O₃ gas when the wafers W pass through below the reaction gas nozzle 32. Namely, every time the wafers W pass through the first area 481 and the second area 482, one molecular layer (or two or more molecular layers) of silicon oxide is formed on the upper surface of the wafers W. After the turntable 2 is rotated predetermined times, the silicon oxide film having a predetermined thickness is obtained on the upper surface of the wafers W, and then the BTBAS gas and the O₃ gas are shut off and the turntable 2 is stopped. Subsequently, the wafers W are transferred out from the vacuum chamber 1 by procedures that are substantially opposite to the procedures with which the wafers W are transferred in. With this, the film deposition process is completed.

According to the film deposition apparatus 10, the sixteen wafers W, each of which has a diameter of 300 mm, can be placed on the turntable 2. Therefore, production throughput may be enhanced by a factor of 3.2, compared to when the five wafers W are placed on a turntable having five wafer receiving areas.

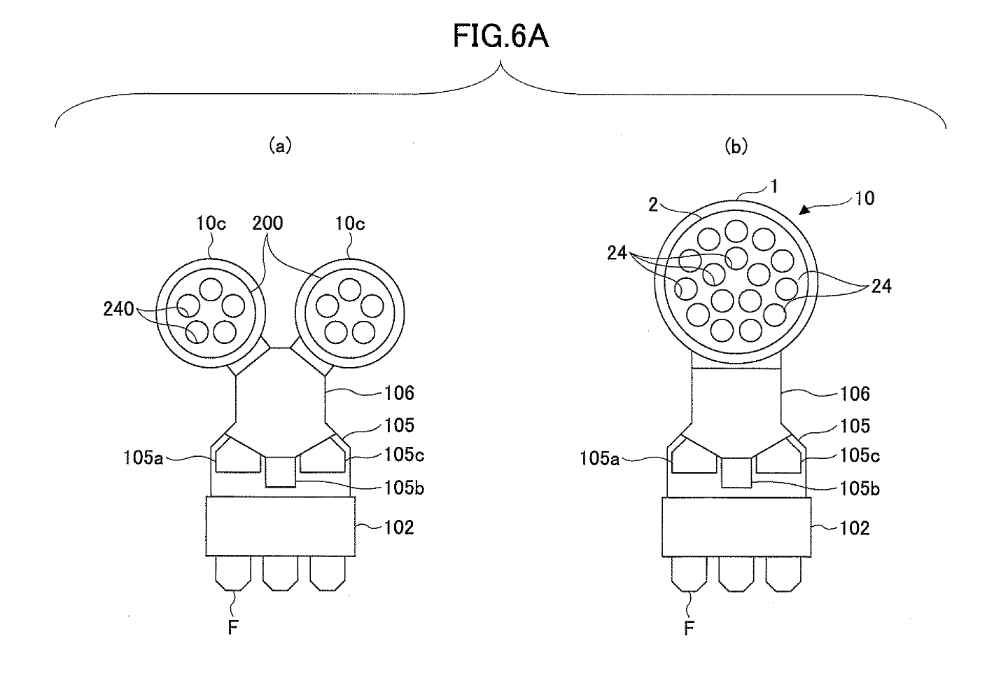

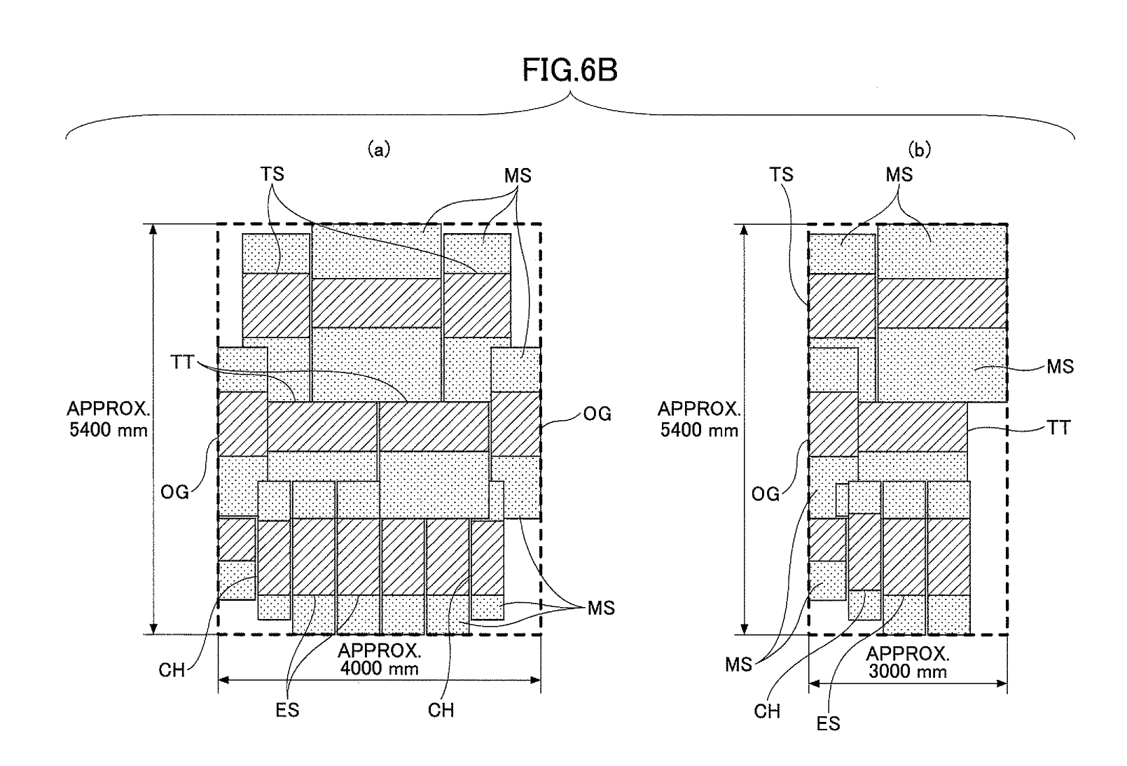

In addition, when compared with a film deposition apparatus having, for example, two vacuum chambers, each of which has a turntable on which five 300 mm wafers can be placed, the film deposition apparatus 10 according to this embodiment can provide the following advantages. Part (a) of FIG. 6A illustrates a film deposition system as a comparative example, which includes two vacuum chambers 10c, a vacuum transfer chamber 106 that is connected to the vacuum chambers 10c, an atmospheric transfer chamber 102 that connects the vacuum transfer chamber 106 and load lock chambers 105a through 105c, and a stage F on which wafer carrier such as Front-Opening Unified Pods (FOUPs) are placed. As shown, the vacuum chambers 10c are provided inside each with a turntable 200 having five wafer receiving areas 240, each of which can accommodate a 300 mm wafer.

On the other hand, part (b) of FIG. 6B illustrates a film deposition system including the film deposition apparatus 10 according to an embodiment of the present invention, the vacuum transfer chamber 106, the atmospheric transfer chamber 102 that connects the load lock chambers 105a through 105c to the vacuum transfer chamber 106, and the stage F. Part (a) of FIG. 6B illustrates ancillary facilities that may be installed for the film deposition apparatus of part (a) of FIG. 6A, for example, in a basement floor of a clean room where the film deposition apparatus of part (a) of FIG. 6A is placed. As shown, the ancillary facilities include two transformers TS, two ozone generators OG, two chillers CH, four evacuation apparatuses ES, and two intoxicating apparatuses TT, which reflect the two vacuum chambers 10c. In addition, maintenance spaces MS are set aside around the transformers TS and the like. The ancillary facilities occupy a total area of about 21.6 m² (about 5.4 m×about 4 m, as shown).

On the other hand, as shown in part (b) of FIG. 6B, only an area of 16.2 m² (about 5.4 m×about 3, as shown) is required for ancillary facilities, in the case of the film deposition system having the film deposition apparatus 10 according to an embodiment of the present invention, which is illustrated in part (b) of FIG. 6A, because only single corresponding components are required even if some of them may be enlarged. Therefore, the area for the ancillary facilities to be saved is by about 25% (21.6−16.2)/16.2).

Incidentally, the film deposition systems illustrated in part (a) of FIG. 6A and part (b) of 6B have different footprints, which corresponds to a difference between the two vacuum chambers 10c in part (a) of FIG. 6A and the vacuum chamber 1 in part (b) of FIG. 6B because other components such as the transfer chamber 106 are the same between the two systems. Because the vacuum chamber 10c has an outer diameter of about 1.6 m, the two vacuum chambers 10c occupy a floor area of about 4.02 m² ((1.6/2)2×π×2). On the other hand, because the vacuum chamber 1 has an outer diameter of about 2.4 m, it occupies a floor area of about 4.52 m² ((2.4/2)2×π), which is greater than the floor area of 4.02 m² for the two vacuum chambers 10c. However, the vacuum chambers 10c, 1, the vacuum transfer chamber 106, and the like, which can be isolated from an ambient environment, can be placed in a maintenance zone (with a lower degree of cleanness) of the clean room. Therefore, the increase in the foot print of the film deposition system having the film deposition apparatus 10 does not provides significant influence on the floor area of the clean room.

In addition, as stated previously, the separation spaces H can be easily maintained with the separation gases from the separation gas nozzles 41, 42 at higher pressure than the pressures of the first area 481 and the second area 482 because the height h1 of the separation space H (FIG. 4) is smaller than the heights of the first area 481 and the second area 482 in the film deposition apparatus 10. Therefore, the first area 481 and the second area 482 are certainly separated. In other words, the first reaction gas and the second reaction gas are not intermixed with each other at the gaseous phase in the vacuum chamber 1. Incidentally, the N₂ gas that has flowed out from the separation space H to the first area 481 and the second area 482 tends to flow above the reaction gas nozzle 31 and the reaction gas nozzle 32, respectively, because the reaction gas nozzle 31 and the reaction gas nozzle 32 are positioned close to the upper surface of the turntable 2 and away from the ceiling plate 11. Therefore, the first reaction gas and the second reaction gas, which are supplied from the reaction gas nozzle 31 and the reaction gas nozzle 32, respectively, are not greatly diluted by the N₂ gas.

Incidentally, in this embodiment, the turntable 2 is not limited to one having 16 wafer receiving areas 24 as illustrated in FIG. 1, but may be altered in various ways. For example, the turntable 2 may have five wafer receiving areas 24 in the inner area and ten wafer receiving areas 24 in the circumferential area, so that fifteen wafers W having a diameter of 300 mm can be placed in total, as shown in a part (a) of

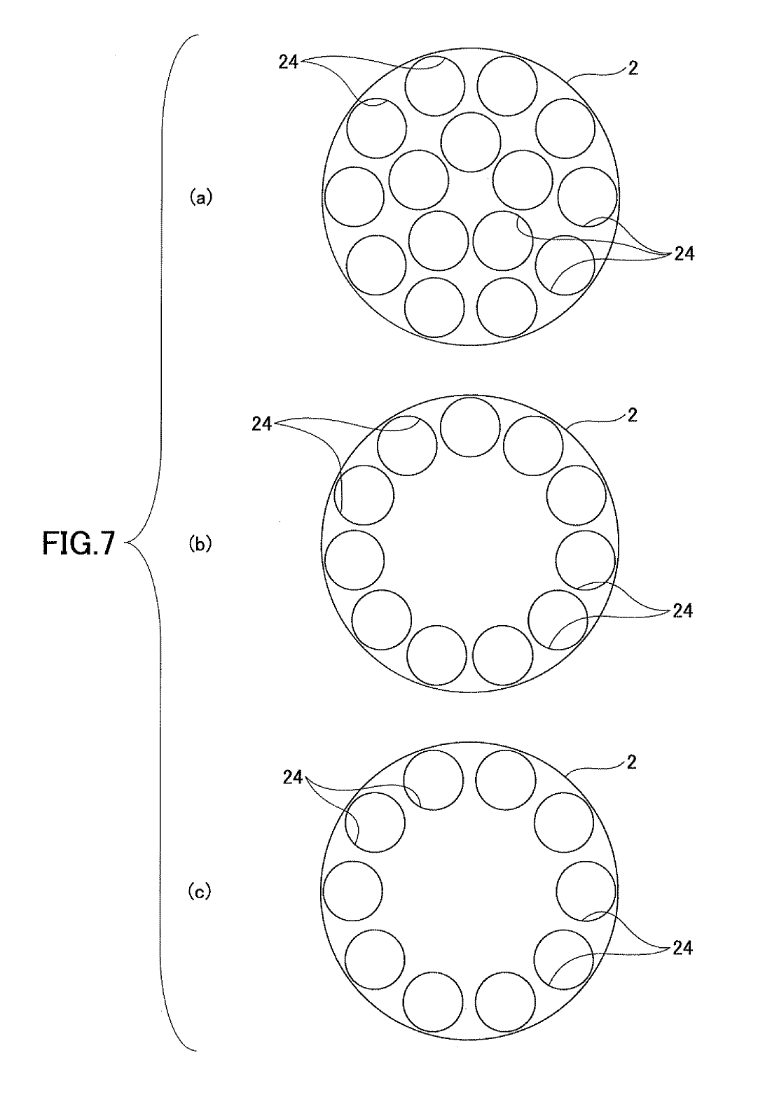

FIG. 7. In addition, the turntable 2 may have ten or eleven wafer receiving areas 24 only in the circumferential area (or an area along the circumference of the turntable 2) as shown in parts (b) and (c) of FIG. 7. Even when the wafer receiving areas 24 are provided in the circumferential area, the production through put can be enhanced, when compared to when the turntable 2 has five wafer receiving areas 24.

### A Second Embodiment

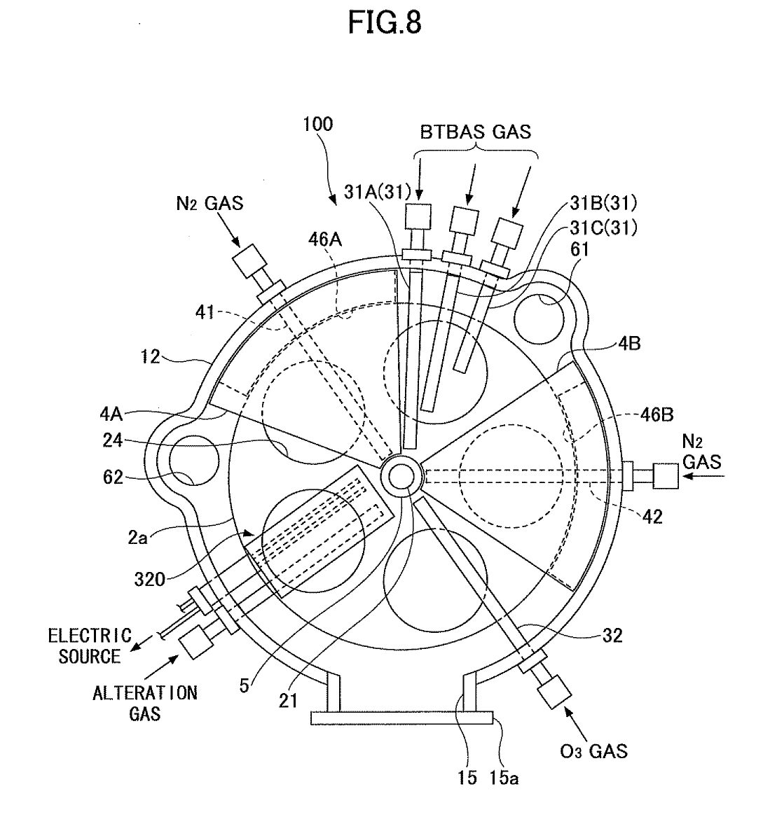

Next, the film deposition apparatus 10 according to a second embodiment of the present invention is explained with reference to FIGS. 8 through 11. In the following, differences of the film deposition apparatus 10 according to the second embodiment with respect to the film deposition apparatus 10 according to the first embodiment is focused on, and the explanation on the same configurations is omitted.

As shown in FIG. 8, a turntable 2a of a film deposition apparatus 100 is provided with five wafer receiving areas 24, each of which can receive a wafer W having a diameter of 450 mm. In addition, the turntable 2a is provided with the wafer supporting portions 24a, the lift pins 16a, the wafer guide rings 18, the claws 18a, the lift pins 16b, and the like, for the wafer receiving areas 24.

In addition, the film deposition apparatus 100 is provided with three reaction gas nozzles 31A, 31B, 31C that supply the first reaction gas (e.g., BTBAS gas). These gas nozzles 31A, 318, 31C are introduced into the vacuum chamber 1 through the circumferential wall of the chamber body 12, and supported in order to extend in the radius direction of the turntable 2a and in parallel with the upper surface of the turntable 2a. A distance between the reaction gas nozzles 31A, 31B, 31C and the upper surface of the turntable 2a may be, for example, about 0.5 mm through about 4 mm. As shown in the drawing, the reaction gas nozzles 31A, 31B, 31C have different lengths. Specifically, the reaction gas nozzle 31A is the longest among them; the reaction gas nozzle 31C is the shortest among them; and the reaction gas nozzle 318 is between the gas nozzles 31A, 31C in terms of the length. In addition, each of the gas nozzles 31A, 31B, 31C is provided with plural ejection holes (not shown) that are open toward the turntable 2 and arranged along the longitudinal direction. Diameters of the ejection holes may be, for example, about 0.5 mm.

In addition, each of the gas nozzles 31A, 31B, 31C is connected to a reaction gas supplying source of the first reaction gas via corresponding gas lines (not shown), each of which has a flow rate controller such as a mass flow controller (not shown). With this configuration, flow rates of the first reaction gas supplied through the reaction gas nozzles 31A, 318, 31C can be independently controlled.

According to the three reaction gas nozzles 31A, 318, 31C, while the first reaction gas is supplied uniformly along the radius direction of the turntable 2a from the reaction gas nozzle 31A, the first reaction gas can be supplied also from the reaction gas nozzles 318, 31C, so that substantive concentration reduction of the first reaction gas in an outer area of the turntable 2a can be suppressed. Because a line speed of the turntable 2a becomes greater and a gas flow speed is greater due to the rotation of the turntable 2a in the outer area of the turntable 2a, it may become difficult for the first reaction gas to be uniformly adsorbed. However, because the reaction gas nozzles 318, 31C can supply the first reaction gas to the outer area of the turntable 2a, the first reaction gas can be uniformly adsorbed on the wafers W.

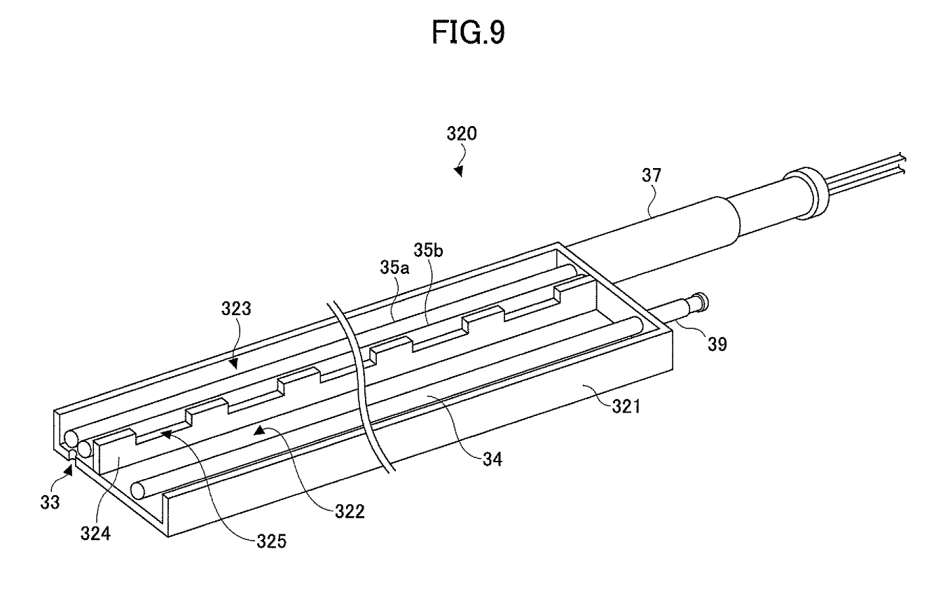

In addition, the film deposition apparatus 100 is provided with a gas injector 320 that activates a predetermined gas with plasma and supplies the activated gas to the wafers W. The gas injector 320 is explained with reference to FIGS. 9 through 11.

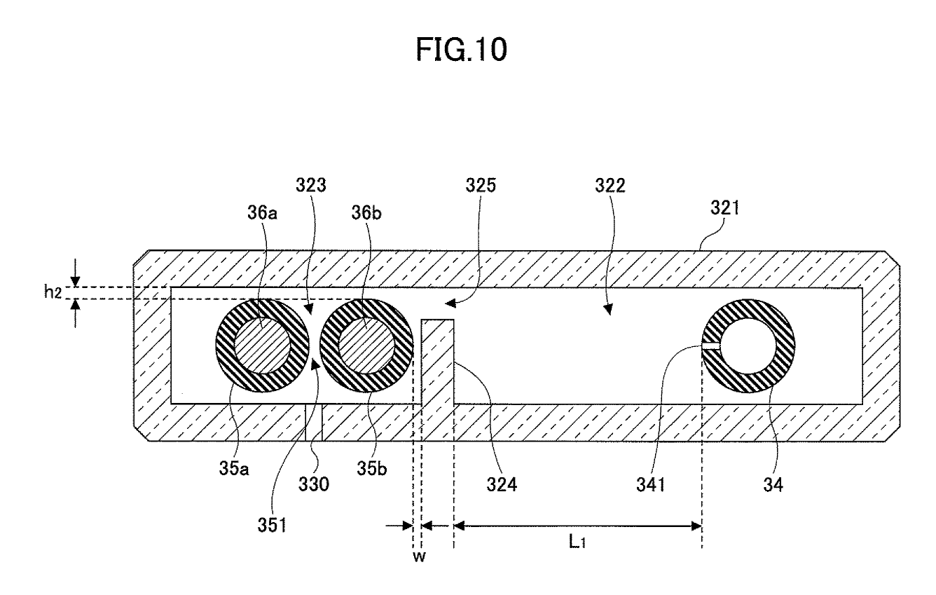

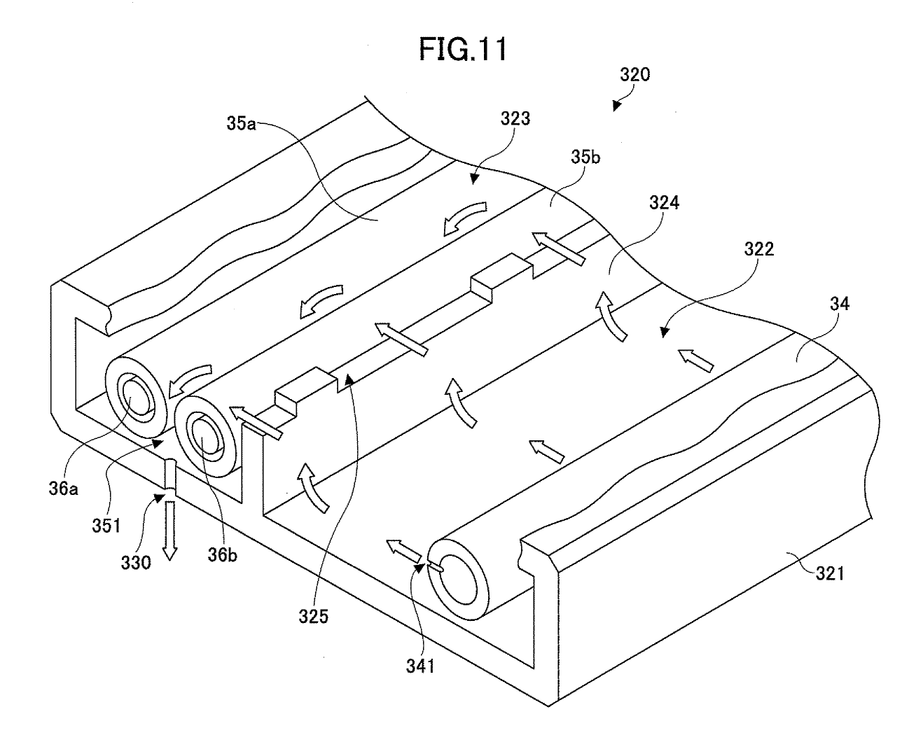

As shown in FIG. 9, the activated gas injector 32 includes a gas injector body 321 as a passage defining member having a shape of a flattened elongated rectangular parallelepiped. The gas injector body 321 is hollow as shown in FIGS. 9 and 10, and made of quartz, which has an excellent resistance against plasma etching, for example. The hollow space inside the gas injector body 321 is divided into two different spaces by a partition wall 324. The spaces extend in the longitudinal direction and have different widths. One of the spaces is a gas activation chamber 323 as a gas activation passage where a predetermined gas is activated into plasma, and the other space is a gas introduction chamber 322 as a gas introduction passage from which the predetermined gas is uniformly introduced into the gas activation chamber 323. As shown in FIG. 11, a ratio of a width of the gas activation chamber 323 with respect to that of the gas introduction chamber 322 is about ⅔, which means the gas introduction chamber 322 has a larger volume.

Referring to FIGS. 10 and 11, a tubular gas introduction nozzle 34 is arranged in the gas introduction chamber 322 so that the gas introduction nozzle 34 extends from a base end to a distal end of the gas introduction chamber 322 along the partition wall 324. The gas introduction nozzle 34 has gas holes 341 that are formed in a circumferential surface of the gas introduction nozzle 34 and open toward the partition wall 324. The gas holes 341 are arranged at predetermined intervals in the longitudinal direction of the gas introduction nozzle 34 and allow the predetermined gas to flow through into the gas introduction chamber 322. On the other hand, a base end of the gas introduction nozzle 34 is connected to a gas introduction port 39 at a side wall of the gas injector body 321 (FIG. 9). The gas introduction port 39 is connected to a gas supplying port (not shown), from which the predetermined gas is supplied to the gas introduction nozzle 34 through the gas introduction port 39.

Elongated rectangular cut-out portions 325 are formed at predetermined intervals along the longitudinal direction (a longitudinal direction of electrodes 36a, 36b described later) in an upper portion of the partition wall 324 opposing the gas introduction nozzle 34. The cut-out portions 325 and a ceiling surface of the injector body 12 define rectangular through-holes that allow the predetermined gas to flow from the gas introduction chamber 322 into an upper part of the gas activation chamber 323. Here, a distance “L1” from the gas holes 341 of the gas introduction nozzle 34 to the partition wall 324 is set to be long enough to allow the predetermined gas ejected out from the gas holes 341 to spread in the longitudinal direction so that the gas concentration becomes uniform.

In the gas activation chamber 323, two sheath pipes 35a, 35b made of dielectric materials, for example, ceramics, extend from the base end to the distal end of the gas activation chamber 323 along the partition wall 324. The sheath pipes 35a, 35b are horizontally arranged in parallel with each other with a gap therebetween. Electrodes 36a, 36b that are made of, for example, nickel alloy, which has an excellent heat resistance, and have a diameter of about 5 mm, are inserted into the corresponding sheath pipes 35a, 35b in the direction from the base end to the distal end (FIG. 10). Specifically, the electrodes 36a, 36b are arranged in parallel with each other leaving a distance of, for example, 2 mm through 10 mm, preferably 4 mm between the electrodes 36a, 36b, and are surrounded by the corresponding sheath pipes 35a, 35b made of ceramics. Base ends of the electrodes 36a, 36b are drawn out from the gas injector body 321, and connected to a high frequency power source (not shown) via a matching box (not shown) outside of the vacuum chamber 1. With this, high frequency power at a frequency of, for example, 13.56 MHz is supplied at a power level of, for example, 10 W through 200 W, preferably 100 W, to the electrodes 36a, 36b, which causes capacitively-coupled plasma in a plasma generation space 351 between the two sheath pipes 35a, 35b, thereby activating the predetermined gas flowing through the plasma generation space 351. Incidentally, the sheath pipes 35a, 35b also extend out through the base end wall of the injector body 321 and the extended-out portions of the sheath pipes 35a, 35b are surrounded by a guard pipe 37 made of, for example, ceramics.

The injector body 321 has in its bottom below the plasma generation space 351 gas ejection holes 330 that allow the activated gas to flow downward. The gas ejection holes 330 are arranged at predetermined intervals along the longitudinal direction of the electrodes 36a, 36b. In addition, a ratio of a distance “h2” (FIG. 10) between the ceiling surface of the gas activation chamber 323 and the sheath pipe 35a (35b) with respect to a distance “w” between the partition wall 324 and the sheath pipe 35b is determined to be, for example, h2≧w. Therefore, the predetermined gas flowing into the gas activation chamber 323 from the gas introduction chamber 322 mainly flows through the plasma generation space 351, rather than a space between the partition wall 324 and the sheath pipe 35b, into the gas ejection holes 330.

The gas injector body 321 so configured is cantilevered by attaching the introduction port 39 and/or the guard pipe 37 to the circumferential wall of the chamber body 12, and extended so that the distal end of the gas injector body 321 is directed toward the center of the turntable 2. In addition, the bottom of the gas injector body 321 is located so that a distance between the gas ejection holes 330 of the gas activation chamber 323 and the wafer W placed in the concave portion 24 of the turntable 2 is within a range, for example, from 1 mm to 10 mm, preferably 10 mm. The gas injector body 321 is detachably attached to the chamber body 12, and the guard pipe 37 is fixed to the chamber body 12 via, for example, an O-ring (not shown), thereby keeping the airtightness of the vacuum chamber 1.

The predetermined gas supplied to the gas introduction nozzle 34 of the gas injector 320 may be, for example, O₂ gas. In this case, because the activated O₂ gas can be supplied to the wafer W, the silicon oxide film formed through oxidation of the BTBAS gas adsorbed on the upper surface of the wafer W with the O₃ gas can be densified, and/or impurities such as organic substances in the silicon oxide film can be eliminated. On the other hand, the predetermined gas may be, for example, ammonia (NH₃) gas. With this, the activated NH₃ gas or nitrogen active species can be adsorbed on the surface of the silicon oxide film formed from the BTBAS gas and the O₃ gas, so that silicon oxynitride film can be obtained.

According to the film deposition apparatus 100, because the five 450 mm wafers can be placed on the turntable 2a, the production throughput can be enhanced, compared to when the five 300 mm wafers are placed.

In addition, because the three reaction gas nozzles 31A, 31B, 31C that supply the first reaction gas are provided in the film deposition apparatus 100, the first reaction gas can be adsorbed uniformly along the radius direction of the turntable 2a, which contributes to improved uniformity of thickness and film properties of the film deposited on the wafers W.

Moreover, because the film deposition apparatus 100 is provided with the gas injector 320, the alteration gas is activated and then supplied to the wafers W, so that properties of the film formed from the first reaction gas supplied from the reaction gas nozzles 31A, 31B, 31C and the second reaction gas supplied from the reaction gas nozzle 32 can be improved.

### A Third Embodiment

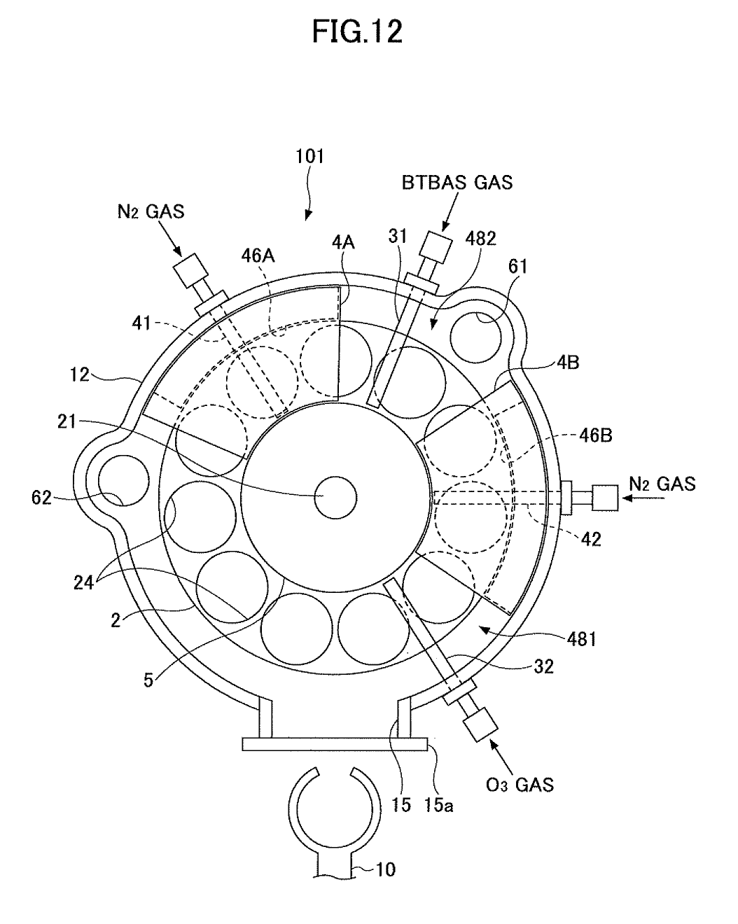

Next, a film deposition apparatus according to a third embodiment of the present invention is explained with reference to FIG. 12. As shown, a film deposition apparatus 101 according to this embodiment includes the turntable 2 that is the same as the one illustrated in part (b) of FIG. 7. The turntable 2 has eleven wafer receiving areas 24 along the outer circumferential edge and no wafer receiving areas in the inner area. In accordance with the inner area without the wafer receiving areas, a diameter of the protrusion portion 5 becomes larger, and thus the inner arc length of the convex portions 4A, 4B becomes greater. In terms of these configurations, the film deposition apparatus 101 is different from the film deposition apparatus 10 according to the first embodiment, and except for these differences, the film deposition apparatus 101 is substantially the same as the film deposition apparatus 10.

Because the protrusion portion 5 has a larger diameter and thus covers the inner area where no wafer receiving areas are formed in the turntable 2, a space between the protrusion portion 5 and the turntable 2 is enlarged, so that the first reaction gas supplied from the reaction gas nozzle 31 and the second reaction gas nozzle 32 are not intermixed through the space H. In addition, because the inner arc of the convex portion 4A (or 4B) becomes longer as the diameter of the protrusion portion 5 becomes larger, the first reaction gas (or the second reaction gas) supplied to the first area 481 (or the second area 482) from the reaction gas nozzle 31 (or the reaction gas nozzle 32) is less likely to go through a boundary area between convex portion 4A (or 45) to reach the second area 482 (or the first area 481). In other words, intermixture of the first reaction gas and the second reaction gas through the boundary can be certainly avoided. If the pressure in the vacuum chamber 1 is lower (e.g., about 1 Torr) and thus the pressure difference between the separation space H and the first area 481 (or the second area 482) may be smaller, the first reaction gas may flow into the second area 482 through the boundary area between the convex portion 4A (or 4B) and the protrusion portion 5. However, according to this embodiment, a length of the boundary can be greater because of the larger diameter of the protrusion portion 5 that corresponds to the inner area where no wafer receiving areas 24 are formed in the turntable 2, thereby providing a greater separation effect of the first and the second reaction gases.

In addition, because the eleven 300 mm wafers W can be placed on the turntable 2, the production throughput can be enhanced, compared to when only five wafers W are placed.

The present invention has been described with reference to several embodiments, but is not limited to the precedent embodiments. The present invention can be modified or altered within a scope of the accompanying claims.

For example, the turntable 2a of the film deposition apparatus 100 according to the second embodiment may be used in the film deposition apparatus 10 according to the first embodiment, and the turntable in the first embodiment may be used in the second embodiment. In addition, the turntable 2 illustrated in FIG. 7 may be used in the film deposition apparatus 100 according to the second embodiment. Namely, a turntable having the wafer receiving areas for 300 mm wafers and a turntable having the wafer receiving areas for 450 mm wafers are exchangeably used in the film deposition apparatus according to an embodiment of the present invention, so that films are deposited on 300 mm wafers or 450 mm wafers. Therefore, the film deposition apparatus according to an embodiment of the present invention can provide a great advantage in that the film deposition apparatus can be continuously used even when a wafer size is changed from 300 mm to 450 mm. Specifically, there is no need of purchasing a film deposition apparatus for 450 mm wafers or retrofitting a film deposition apparatus for 300 mm wafers into a film deposition apparatus for 450 mm wafers.

Incidentally, it is easy to exchange the turntables 2 (2a) by removing and setting the core portion 21, as explained with reference to FIG. 3.

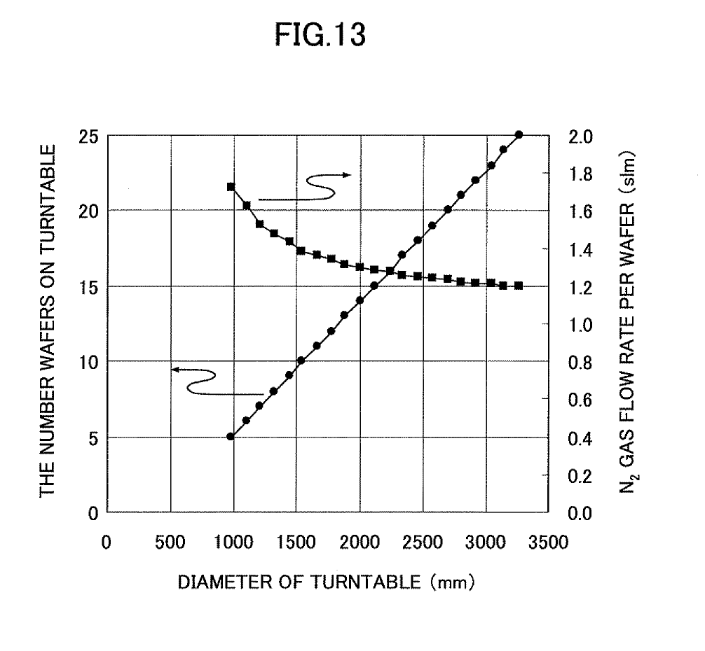

In addition, the number of the wafer receiving areas 24 is not limited to those exemplified above, but may be arbitrarily changed. For example, as the number of the wafer receiving areas 24 is increased, an amount of the N1 gas required per wafer can be reduced, thereby reducing production costs of semiconductor devices. FIG. 13 illustrates a result of computer simulation carried out to determine an amount of the N₂ gas that should be supplied to the separation space H from the separation gas nozzles 41, 42 in order to separate the first area 481 and the second area 482. In this simulation, the amount of the N₂ gas is shown as a function of the number of the wafers, taking into consideration a diameter of the turntable on which the corresponding plural wafers can be placed, a size of the vacuum chamber 1 that can accommodate the turntable, and sizes of the convex portions 4A, 45 in accordance with the size of the vacuum chamber. As shown in the graph, as the diameter of the turntable is increased, the number of the wafers (300 mm) that can be placed on the turntable is increased. Because of an increased size of the vacuum chamber, it may be thought that the amount of the N₂ gas to be supplied should be increased. However, on the contrary, the amount of the N₂ gas per wafer is decreased, even if the size of the vacuum chamber 1 is increased or the number of the wafers is increased.

Moreover, while the groove 43 is formed in the convex portion 4A (or 4B) so that it bisects the convex portion 4A (or 4B) in the above embodiments, it may be formed in a downstream side of the convex portion 4A (or 4B) so that the ceiling surface 44 (or the lower surface of the convex portion 4A (or 4B) is enlarged in an upstream side thereof.

In addition, the reaction gas nozzles 31 (31A through 31C), 32 may extend from the center portion of the vacuum chamber 1 instead of from the circumferential wall of the chamber body 12 of the film deposition apparatuses 10, 100, 101 in other embodiments. Moreover, the reaction gas nozzles 31 (31A through 31C), 32 may extend at a predetermined angle with respect to the radius direction of the turntable 2.

In addition, while the reaction gas nozzles 31A through 31C are used to supply the first reaction gas (e.g., BTBAS gas or silicon containing gas) in the second embodiment, plural reaction gas nozzles having different lengths may be used to supply the second reaction gas (e.g., O₃ gas). Moreover, such plural reaction gas nozzles may be used in the film deposition apparatus 10 in the first embodiment and the film deposition apparatus 101 in the third embodiment. Furthermore, the gas injector 320 may be used in the first embodiment and the film deposition apparatus 101 in the third embodiment.

Incidentally, a length of the convex portions 4A, 4B, which is measured along the rotation direction of the turntable 2 (2a), may range from about one-tenth of a diameter of the wafer W through about a diameter of the wafer W, preferably, about one-sixth or more of the diameter of the wafer W in terms of an arc that corresponds to a route through which a wafer center passes.

The film deposition apparatus according to an embodiment of the present invention is applicable to ALD (or MLD) film deposition of a silicon nitride film. In addition, the film deposition apparatus according to an embodiment of the present invention is applicable to ALD (or MLD) film depositions of an aluminum oxide film using Trimethyl Aluminum (TMA) gas and O₃ gas, a zirconium oxide film using tetrakis-ethyl-methyl-amino-zirconium (TEMAZr) gas and O₃ gas, a hafnium oxide film using tetrakis-ethyl-methyl-amino-hafnium (TEMAH) gas and O₃ gas, a strontium oxide film using bis(tetra methyl heptandionate) strontium (Sr(THD)₂) gas and O₃ gas, a titanium oxide film using (methyl-pentadionate)(bis-tetra-methyl-heptandionate) titanium (Ti(MPD)(THD)) gas and O₃ gas, or the like. In addition, O₂ plasma may be used instead of the O₃ gas. Moreover, combinations of any gases recited above may be used.

What is claimed is:

1. A film deposition apparatus for depositing a film on a substrate by carrying out a cycle of alternately supplying at least two kinds of reaction gases that react with each other to the substrate to produce a layer of a reaction product in a chamber, the film deposition apparatus comprising:
a first turntable rotatably provided in the chamber, wherein the first turntable includes at least ten substrate receiving areas in each of which the substrate having a diameter of 300 mm is placed;
a first reaction gas supplying portion that is arranged in a first area inside the chamber, extends in a direction transverse to a rotation direction of the first turntable, and supplies a first reaction gas toward the first turntable;
a second reaction gas supplying portion that is arranged in a second area that is away from the first reaction gas supplying portion along the rotation direction of the first turntable, extends in a direction transverse to the rotation direction of the first turntable, and supplies a second reaction gas toward the first turntable;
a first evacuation port provided for the first area;
a second evacuation port provided for the second area; and
a separation area arranged between the first area and the second area,
wherein the separation area includes
a separation gas supplying portion that supplies a separation gas that separates the first reaction gas and the second reaction gas in the chamber, and
a ceiling surface having a height from the first turntable so that a pressure in a space created between the ceiling surface and the first turntable is higher with the separation gas supplied from the separation gas supplying portion than pressures in the first area and the second area.

2. The film deposition apparatus of claim 1, further comprising a supporting portion that exchangeably supports the first turntable, wherein the first turntable may be replaced with a second turntable having at least five wafer receiving areas in each of which a 450 mm wafer is placed.

3. The film deposition apparatus of claim 1, wherein at least one of the first reaction gas supplying portion and the second reaction gas supplying portion includes plural gas nozzles that extend in a direction transverse to the rotation direction of the first turntable and have different lengths.

4. The film deposition apparatus of claim 3, further comprising a gas injector that includes
a flow passage forming member that is partitioned by a partition wall into a gas introducing chamber into which a gas is introduced and a gas activating chamber where the gas introduced from the gas introducing chamber;
a gas introducing port that introduces the gas into the gas introducing chamber;
a pair of electrodes that extend in parallel with each other along the partition wall in the gas activating chamber, wherein electric power is applied across the pair of electrodes;
gaseous communication holes that are arranged along a longitudinal direction of the pair of the electrodes and supply the gas activated in the gas activating chamber toward the first turntable.

5. The film deposition apparatus of claim 1, wherein the first turntable includes
at least one groove portion that surrounds corresponding one of the substrate receiving areas, and
a substrate guide ring that has a diameter greater than a diameter of the substrate and may be fitted into the groove portion, wherein the substrate guide ring includes a claw portion extending inward beyond an outer circumferential edge of the substrate placed in the corresponding one of the substrate receiving areas.

6. The film deposition apparatus of claim 2, wherein the second turntable includes
at least one groove portion that surrounds corresponding one of the substrate receiving areas, and
a substrate guide ring that has a diameter greater than a diameter of the substrate and may be fitted into the groove portion, wherein the substrate guide ring includes a claw portion extending inward beyond an outer circumferential edge of the substrate placed in the corresponding one of the substrate receiving areas.
